(19) United States
(12) Patent Application Publication
(10) Pub. No.: US 2014/0318613 A1
(43) Pub. Date: Oct. 30, 2014

(54) SOLAR CELL

(71) Applicants: Hilmar Von Campe, Bad Homburg (DE); Peter Roth, Hanau (DE)

(72) Inventors: Hilmar Von Campe, Bad Homburg (DE); Peter Roth, Hanau (DE)

(73) Assignee: SCHOTT SOLAR AG, Mainz (DE)

(21) Appl. No.: 14/110,827

(22) PCT Filed: Apr. 12, 2012
(86) PCT No.: PCT/EP2012/056673

§ 371 Date: Dec. 23, 2013

(30) Foreign Application Priority Data
Apr. 12, 2011 (DE) 10 2011 001 999.5

(51) Int. Cl. H01L 31/02; H01L 31/0224

(52) U.S. Cl. CPC H01L 31/0201; H01L 31/022441
USPC 136/256

(57) ABSTRACT

A solar cell is provided that includes a semiconductor substrate with a front-side contact and a rear-side contact. The front-side contact includes contact fingers running parallel to one another and at least one busbar running transversely with respect thereto. A connector runs along the busbar and is cohesively connected thereto. In order to avoid cracking in the event of forces acting on the connector, the busbar includes sections that have soldering edges and over which the connector extends.

The invention relates to a solar cell comprising a semiconductor substrate with contacts on the front and back sides, whereby the front-side contact preferably comprises contact fingers running parallel to one another and at least one busbar running crosswise to these fingers, with a connector connected to this busbar running along with it.

In the production of crystalline silicon solar cells, to which the invention relates, usually sawed Si wafers are textured by means of an etching bath. Subsequently, phosphorus can be diffused into one side of the wafer according to a standard technique, in order to form a pn-junction. For this purpose, during production, a phosphosilicate glass, which serves as the P source for the diffusion process, is applied onto the front side, and is subsequently etched away. A metallizing is then effected by means of conductive pastes.

For the formation of a front grid, two to three or more busbars as well as individual, approximately 100-μm wide, current collectors, also called fingers, are introduced on the radiation side, thus the side facing the sun, which is the n-layer for a p-conducting wafer. This can be carried out by screen printing, “typing”, electrodeposition, or flame spraying/plasma spraying. The screen-printing technique in which a glass-containing Ag conductive paste is printed on, dried and then sintered at approximately 800° C. has also been applied to a considerable extent.

Usually a large-surface aluminum layer is applied as a back contact on the back side of the wafer, thus the side facing away from the radiation or sun. Upon tempering the aluminum at a temperature of approximately 600° C., the silicon substrate is melted at the interface between the aluminum layer and the silicon substrate and is alloyed with the aluminum. During cooling, a silicon layer highly doped with aluminum solidifies epitactically on the back side of the wafer, thus the substrate, which faces the silicon. Simultaneously, an Al layer enriched with silicon solidifies on the side facing the aluminum layer, and upon the conclusion of the cooling process, an Al—Si eutectic solidifies between the layer highly doped with aluminum and the layer enriched with silicon.

The high Al doping in silicon induces an electrical field in the direct vicinity of the back contact, the so-called back-surface field, which keeps away the minority charge carriers in the p region, i.e., the electrons from the back contact, and opposes a recombination at the ohmic back contact. Consequently, a good passivation of the back side against recombinations of minority charge carriers is achieved, so that a high efficiency of the solar cell can be achieved.

In order to carry out the necessary electrical contacting, usually contact conductive tracks or solder points are applied directly onto the substrate surface by screen printing, pad printing, or another suitable printing process and tin-coated copper strips are soldered to these points. The dimensions of corresponding solder points, which are also designated pads, lie between 10 to 20 mm×6 to 8 mm, and typically have a rectangular or oval shape.

Screen printing or pad printing of conductive pastes to glass components is common practice. These pastes are first printed, then dried at 200 to 300° C., and finally sintered or alloyed at temperatures of more than 570° C.

A method for producing solar cells with back-side contacts having an aluminum layer and Ag pads present in the recess of the latter can be taken from US-A-2008/0105297. It is described therein that three metals, namely Al, Ag and Si, interact in the targeted printed overlapping region between the aluminum layer and the Ag pads. Mechanical stresses due to the different thermal expansion of the three components will arise thereby, so that the silver of the back-side pads that is printed on will flake off in the overlapping region. In order to avoid this disadvantage, Ag pads with rounded and chamfered corners will be used, by means of which, the mechanical stress peaks that occur at corners will be reduced. Practical tests of measures in this respect, however, have shown that mechanical stress peaks are not reduced to the extent necessary, so that in addition, a damaging of the silver pads may occur, and thus there is the risk of an inoperability of a corresponding solar cell having these pads.

A wafer-solar cell is known from DE-A-10 2009 026 027, in which, in order to avoid a risk of breaking the wafer, discontinuous busbars are formed in the back-side electrode structure in such a way that an overlapping of the pads is omitted corresponding to the discontinuous busbars and the back-side layer. Since the production technology does not assure that the pads can be introduced exclusively inside the recesses of the back-side layer, considered in the longitudinal direction of the discontinuous busbars, it is proposed that the pads end at a distance from the adjacent layer in the direction of the connector to be soldered on, whereby, however, a distancing is formed predominantly exclusively between the edges of the pads and the layer, without having the gap extend to the back side of the semiconductor substrate. The width of the gap should most preferably be smaller than 400 μm in the region of the edges.

The subject of JP-A-2003-273379 is a solar cell with strip-shaped busbars that have a smaller thickness in the overlapping region with the back side of the solar cell than outside the overlapping region.

US-A-2010/0200057 has strip-shaped busbars with recesses on the back side.

A light diode according to US-A-2003/0025115 has a pad electrode that can be connected to an electrical conductor and a translucent electrode. The pad electrode is structured peripherally.

The object of the present invention is based on enhancing a solar cell of the type named initially, so that a formation of cracks is avoided, or is at least reduced in comparison to the prior art, when forces act on the connector connected to the busbar.

According to another aspect, a damaging of the semiconductor substrate, i.e., the wafer, due to expansion coefficients that are different from each other, shall be avoided regardless of the different materials used for the formation of the back-side contact, but simultaneously a secure, cohesive connection will be assured between the connectors and the solder points, i.e., the pads.

The invention proposes a solar cell comprising a semiconductor substrate with contacts on the front and back sides, in which the front-side contact is preferably composed of contact fingers running parallel to one another and at least one busbar running crosswise to these fingers, with a connector connected to this busbar running along with it, and is characterized in that the at least one busbar is composed of sections and in that the sections have soldering edges over which the connector extends.

Deviating from known constructions, the busbar has a plurality of soldering edges in the region of the front side of the solar cell, i.e., on the side facing the radiation, so that then, if tensile forces act on the connector, there is a distribution of these forces with the result that the formation of cracks, which would otherwise occur, is reduced or prevented.

A soldering edge is the edge along which the connector is cohesively connected to the section of the busbar. Considered from its longitudinal direction, the connector usually is joined with the section over the entire length of this section, so that the edges of the sections that are covered by the connector are also soldering edges.

Here, it is particularly provided that the sections are formed in such a way that preferably at least two contact fingers, in particular precisely two contact fingers, are connected each time to a section of the busbar forming at least two soldering edges. In particular, the invention provides that a section of the busbar connecting at least two contact fingers, in top view, has an annular or hollow-rectangular geometry for the formation of four soldering edges.

Additionally or alternatively, the invention proposes that the busbar is composed of two strip-shaped sections running in its longitudinal direction, each of these sections expanding in width in the region of the fingers and preferably continuously merging into the respective longitudinal edge of the fingers.

Considered from their longitudinal direction, busbars may also be composed of several sections distanced from one another, each segment having at least two transverse soldering edges, i.e., soldering edges that run crosswise to the longitudinal extent of the busbar. There results a conductor geometry with longitudinal and transverse legs. Independently from this, the busbar should be divided into sections in such a way that a maximum of five contact fingers, preferably two contact fingers, are assigned to at least two soldering edges extending along the fingers, at least in sections.

According to the invention, the busbar running on the front side, which is cohesively connected to a cell connector, is divided into sections or regions in such a way that a plurality of soldering edges result, which need not necessarily run perpendicular or crosswise to the longitudinal direction of the busbar. The longitudinal direction of the busbar is pre-defined in this case by the longitudinal extent of the connector along the busbar.

The soldering edge itself need not absolutely run exclusively crosswise to the longitudinal direction of the busbar, thus along or parallel to the contact fingers. Rather, a region of a section of the busbar running obliquely to the contact fingers may also form a soldering edge, in particular, when the busbar is widened in the region of a contact finger, and the longitudinal edges of busbar and contact fingers merge into one another continuously, i.e., a concavely running longitudinal edge of the busbar section is provided as the soldering edge.

In order to achieve the additional aspect of the invention, insofar as the back-side contact is concerned, according to the invention, a solar cell having a semiconductor substrate with front-side and back-side contacts is essentially proposed, the back-side contact having a layer with recesses in which soldering points (pads) are disposed, the layer being composed of or containing a first electrically conducting material, the pads being composed of or containing a second electrically conducting material, which forms an intermetallic compound with the first electrically conducting material in the contact region, whereby soldering points disposed in at least two recesses are connected with a connector running along a straight line in a soldering region of each pad, and the connector extends at a distance from the layer over soldering edges of the soldering point, whereby the solar cell is characterized in that the connector is cohesively connected to the soldering points exclusively outside the intermetallic compound, and/or that the connector extends over at least three soldering edges of the soldering point running crosswise to the straight line, whereby the at least three soldering edges have a length covered by the connector that is at least 2.5 times, preferably 3 times, the width B of the connector.

In particular, the invention provides that a first soldering edge is a first edge region of the pad intersected by the straight line, this region running at a distance from the layer, such as the Al layer or its layer edge covered by the connector, whereby, in particular, each first edge region of the pad runs at a distance from the respective layer edge covered by the connector. The straight line is predefined by the longitudinal axis of the connector.

Further, the first edge region, at least in the soldering region, should have a geometric course that deviates from that of the facing layer edge, i.e., the edge of the back-side layer, which is particularly composed of Al, over which the connector extends. The teaching according to the invention, among other things, utilizes the knowledge of the inventor that has been established by metallographic methods: that the alloying process between the materials, i.e., Al and solderable contact material, and not the encounter between the materials Ag, Al and Si, is the decisive factor responsible for the occurrence of high mechanical stresses in the overlapping region between the pads and the adjacent layer of the back contact, as is described in US-A-2008/0105297.

Aluminum and silver are alloyed in the overlapping region of the pad during sintering. First, aluminum melts and then flows into the porous Ag layer structure. In-situ observations have shown that an approximately 1 to 2 mm wide alloy strip forms due to the outflowing of liquid aluminum. This strip solidifies after cooling as an intermetallic compound (ζ phase, μ phase) according to the phase diagram, which also still contains fractions of elemental Al, Ag and possibly Si. The width of the strip in this case depends on the quantities of the Al and Ag components, i.e., also on the layer thickness and the porosity of the silver. Consequently, the numerical data for a (the distance between the edge of the first edge region of the pad and the facing edge of the connector) are to be construed correspondingly, since the zones may also turn out to be wider or narrower.

For this reason, it is not possible without further measures to print Ag contacts directly onto the aluminum without an intermetallic compound of the type described above being formed during the sintering.

The overlapping region, which is a penetration region in the proper sense, exercises a high mechanical stress on the wafer. Up to 350 MPa was measured with Raman microspectroscopy. A possible explanation for the occurring stress is that the Al—Ag alloy is by far not as ductile as the elemental layers. It should be further taken into consideration that the entire process is finished in several seconds, so that the cooling process is executed still during the formation of the Al/Ag alloy. Consequently, micro-cracks that are aligned parallel to the overlapping zone can occur. Stress cracks still occur additionally, however, if the corresponding pre-stressed areas are mechanically loaded, i.e., if a soldered connector terminates at this site, or if a mechanical stress occurs on the cell due to bending in a temperature cycle.

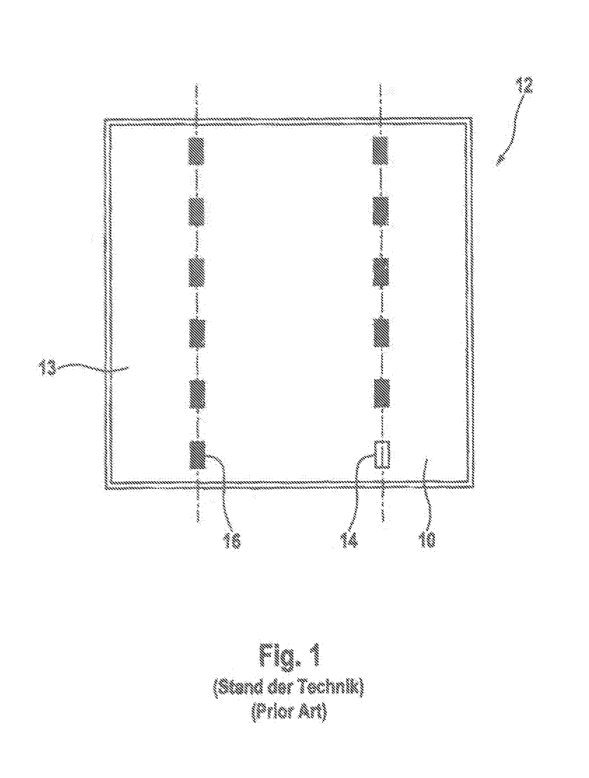

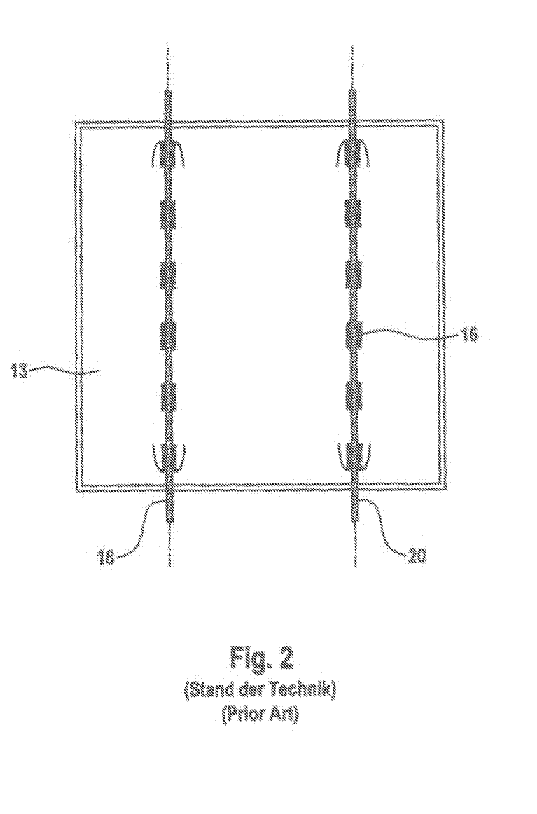

Investigations have indicated that micro-cracks that are formed by tensile stress may occur at both ends of soldered copper connectors, and due to shape and direction, clear hints are offered as to the cause of their formation. This can be explained based on FIGS. 1 and 2, which show a back-contact 10 of a solar cell 12, which has a layer 13 with recesses 14 covering the solar cell 12 on the back side, this layer being composed of aluminum or containing aluminum, the recesses being penetrated by pads 16 preferably having a rectangular shape. Thus far, this involves the back side of a solar cell of previously known construction, i.e., according to the prior art.

If the pads 16 arranged in rows are cohesively connected to copper connectors 18, 20 (FIG. 2), then it could be established that at the ends of the soldering in each case, i.e., the cohesive connections crosswise to the longitudinal direction of the connectors 18, 20, curved cracks are formed running crosswise to the mechanical tensile force that occurs. Upon cooling after soldering, since the copper connector 18, 20, contracts more intensely than the silicon, this type of crack formation is observed increasingly with wafers that become thinner. Occasionally, similar tensile stress cracks also occur on pads that lie further inside.

These cracks occur particularly strongly, however, when the soldering extends into the overlapping region, i.e., the tensile stress of the connector is added to the stress that is produced by the intermetallic alloy.

The disadvantages in this connection are avoided based on the teaching according to the invention. Thus, a mechanical relief and with this the avoidance of a crack formation will be achieved by distributing the mechanical tensile force produced by the connector onto a longer line, and therefore, a smaller stress will be produced. If the stress is distributed, e.g., on 10 soldering edges, then the stress per soldering edge is reduced by a factor of 10. This leads to a smaller load on the material.

It is particularly provided according to the invention that the soldering edge adjacent to the first edge region follows a convex or concave arc section at least in the soldering region relative to the facing edge of the layer. It is particularly provided that the pad is composed of lenticular sections merging into one another or sections that are of oval shape in top view, the longitudinal axes of which run along the straight line pre-defined by the connectors, the respective edge of the second edge region having a V geometry with curved running legs. In this way, the contact region between the connector and the pad is considerably enlarged in the region of the edge in comparison to pads that have a rectangular or circular geometry, and thus stress that may occur is considerably reduced.

By rounding the silver pad in the region of the soldering edges corresponding to the crack form that usually arises, the mechanical tensile stress can be transferred to a longer line. In this way, a rounded shape of the Ag pad is produced in such a way that it does not come into contact with the layer composed of aluminum or containing aluminum. The tensile stress can be reduced corresponding to the ratio of the contacting side lengths.

Further, the contact line necessary in the pads, such as Ag pads, between the pad and the layer can be shifted to regions in which mechanical stress is not produced after soldering relative to the soldered connector, in order to draw off the current from the surface layer, such as the Al layer. By reducing the contact in the pad and the back-side layer, in fact, the electrical contact resistance can be somewhat increased. By optimizing the length of the contact line, however, the disadvantages occurring in this regard can be minimized as needed.

It is provided in an enhancement that the pad has a concavely running arcuate geometry in its respective first edge region with respect to the adjacent back-side layer and/or a convexly running arcuate geometry in its respective first edge region, each time considered in relation to the adjacent layer region of the back side or the layer region running at a distance.

The pad may also have a rectangular geometry in top view, in which the respective edge of the second edge region and the facing edge of the layer each have a concavely running arcuate geometry.

For reducing the tensile stress, it is provided according to another embodiment that in the case of the soldered-on connector, the pad has rectangular, circular or oval-shaped recesses in its soldering region that are covered by the connector, at least in regions in which the circular recess in particular is covered completely, and/or the oval-shaped recess with its longitudinal axis running crosswise to the longitudinal axis of the connector is preferably covered exclusively in regions, i.e., is not completely covered by the connector.

It is particularly provided that the pad disposed in the recess is composed of at least two sections at a distance from one another at least in the region of the recess covered by the connector, whereby each section should have two soldering edges. The soldering edges facing one another proceeding from the sections at a distance from one another can also merge into one another, so that the soldering edges of the sections are, properly speaking, sections of a continuous soldering edge.

In addition, it is provided in an enhancement that the sections are disposed completely at a distance from one another in the recess, i.e., they are separate from one another. In other words, at least two, preferably more than two, strip-shaped soldering regions run inside a recess, the strip-shaped soldering regions being disposed at a distance from one another. The distanced soldering regions thus form the actual soldering points. Further, the outer-lying strip-shaped soldering regions should run at a distance to the layer edges that are covered by the connector.

The emergence of cracks is particularly prevented or reduced by excluding overlapping zones in regions in which there is a direct cohesive connection between the connector and the pad, i.e., in the edge or soldering edge regions of the pads over which the connector extends, thus in the first edge regions running crosswise to the second edge regions in which the intermetallic compounds are formed. Therefore, it is particularly provided according to the invention that in the first edge regions there is a distancing between the edges of the pad facing one another and the layer surrounding these, i.e., a gap is formed, which should at least be in the range between 0.5 mm and 10 mm.

The distancing between the soldering edge and the layer edge can be produced by a special printing design.

In addition, from the geometries of the pads proposed according to the invention, the advantage results that if conductive silver or a material containing silver is used as the second electrically conducting material, there is a savings of silver material, whereby the production costs for solar cells designed according to the invention will be reduced.

Further, the invention provides that the soldering region in which the connector is cohesively connected to the pad runs at a distance to the regions in which the intermetallic compound (alloy) is formed, i.e., relative to the connector, in the edge regions of the pads running parallel to it. In this case, it is particularly provided that the soldering region has a distance a of 0.5 mm≦a≦2 mm, in particular 0.5 mm≦a≦1 mm to the corresponding longitudinal edge, i.e., the respective second edge region of the pad.

Other details, advantages and features of the invention result not only from the claims, and from the features to be derived from the claims—taken alone and/or in combination—but also from the following description of examples of embodiment to be taken from the drawing. Herein:

FIG. 1 shows a view of the back side of a solar cell according to the prior art without connectors;

FIG. 2 shows the solar cell according to FIG. 1 with connectors;

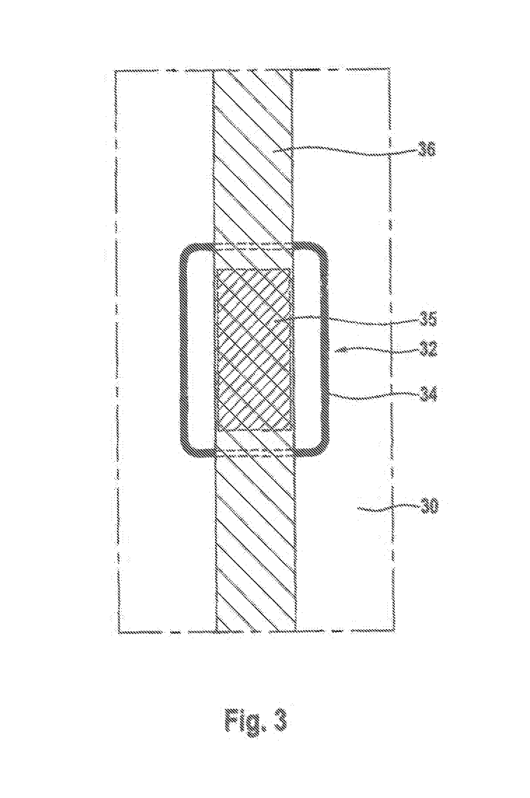

FIG. 3 shows an excerpt of a solar cell with a connector connected to a pad;

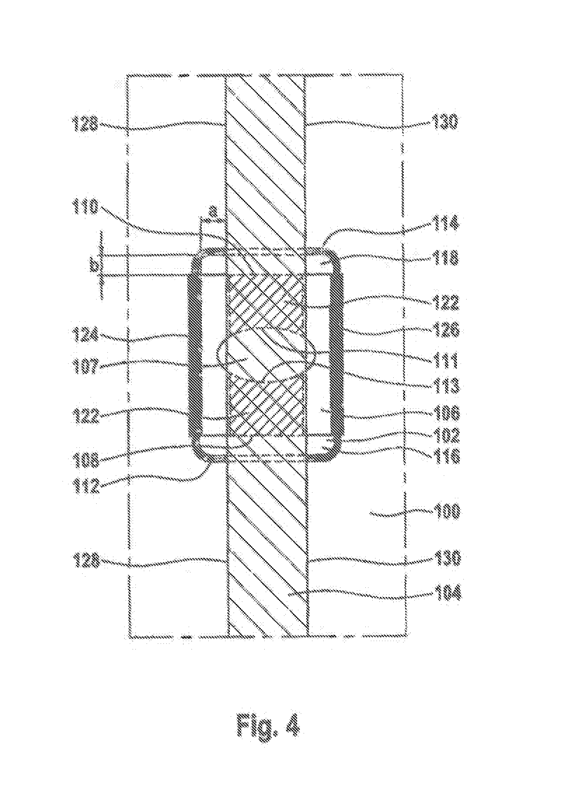

FIG. 4 shows an excerpt of a solar cell with a second embodiment of a back-side contact;

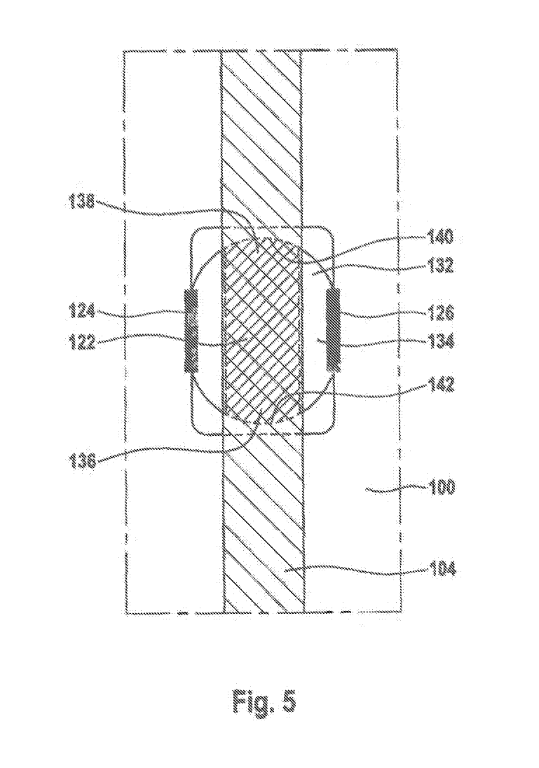

FIG. 5 shows an excerpt of a solar cell with a third embodiment of a back-side contact;

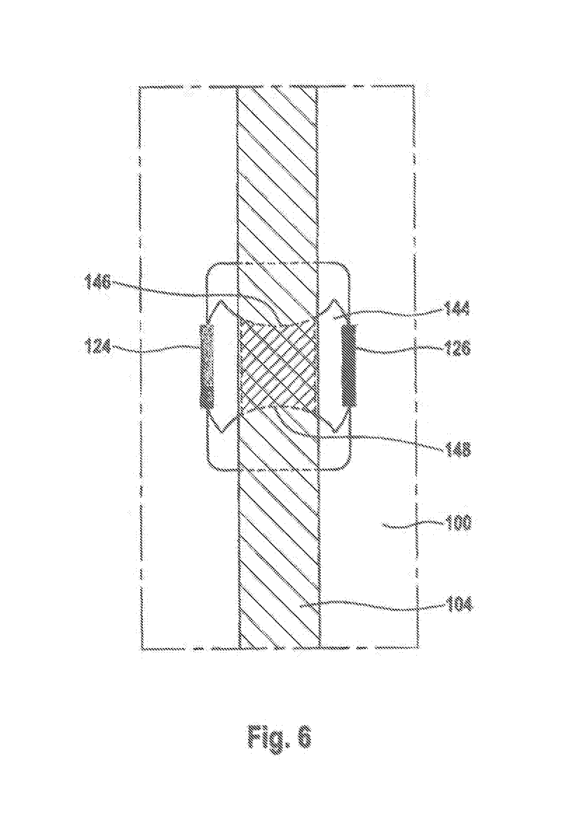

FIG. 6 shows an excerpt of a solar cell with a fourth embodiment of a back-side contact;

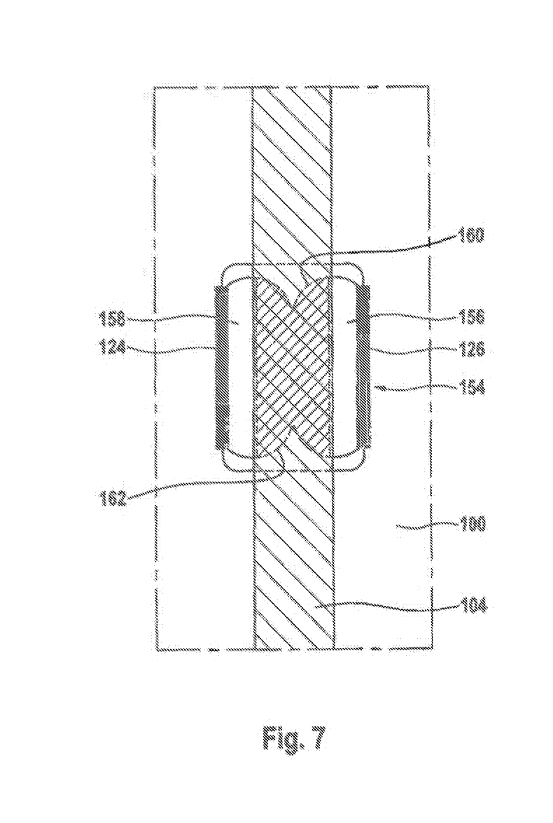

FIG. 7 shows an excerpt of a solar cell with a fifth embodiment of a back-side contact;

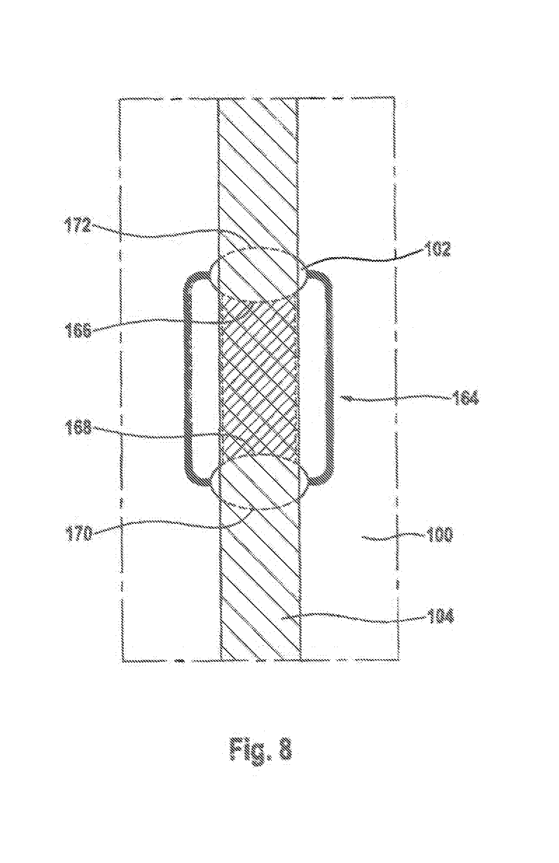

FIG. 8 shows an excerpt of a solar cell with a sixth embodiment of a back-side contact;

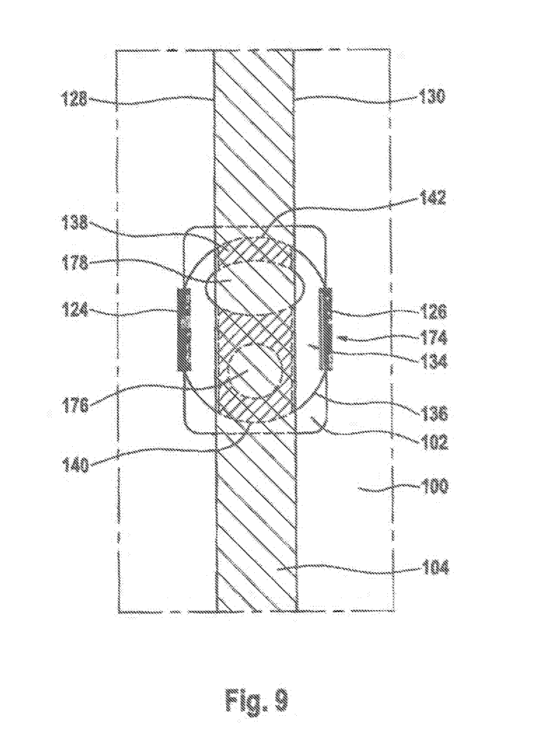

FIG. 9 shows an excerpt of a solar cell with a seventh embodiment of a back-side contact;

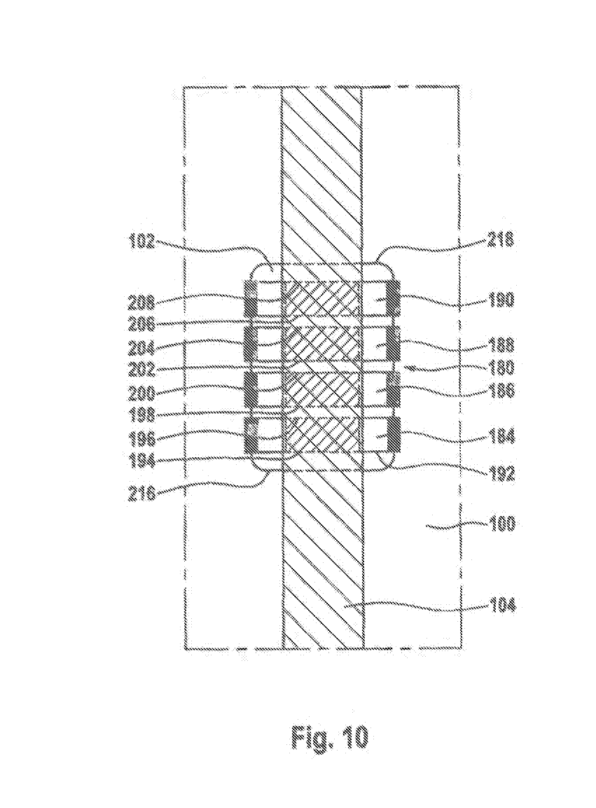

FIG. 10 shows an excerpt of a solar cell with an eighth embodiment of a back-side contact;

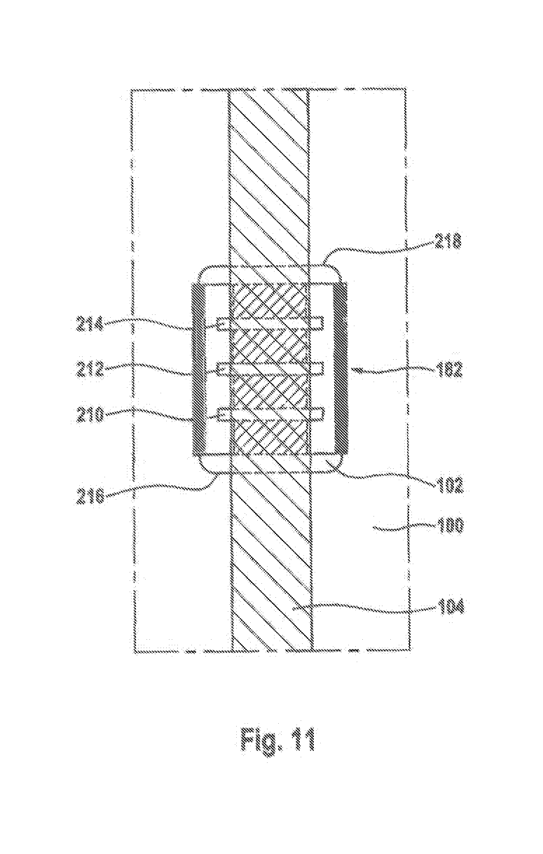

FIG. 11 shows an excerpt of a solar cell with a ninth embodiment of a back-side contact;

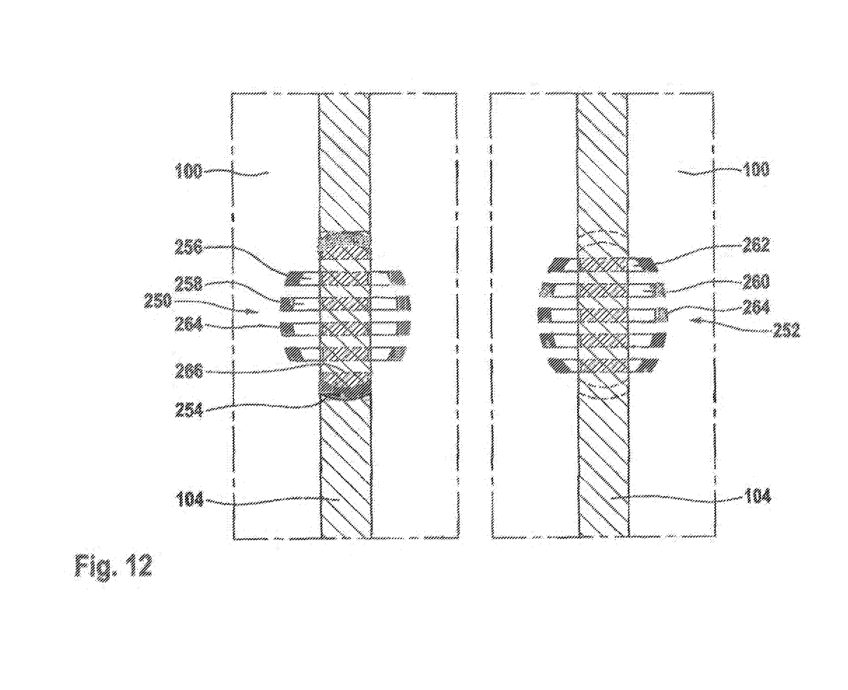

FIG. 12 shows an excerpt of a solar cell with a tenth embodiment of a back-side contact;

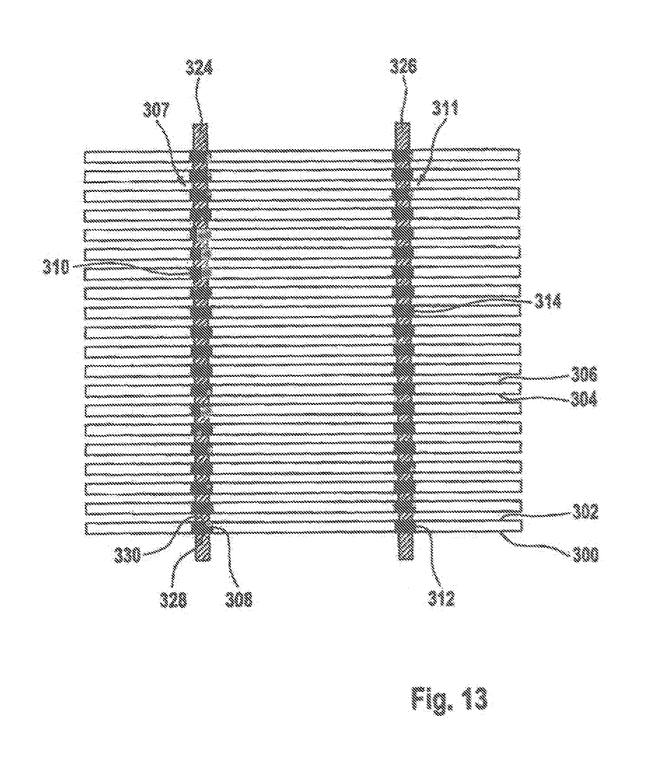

FIG. 13 shows a top view onto a front-side contact;

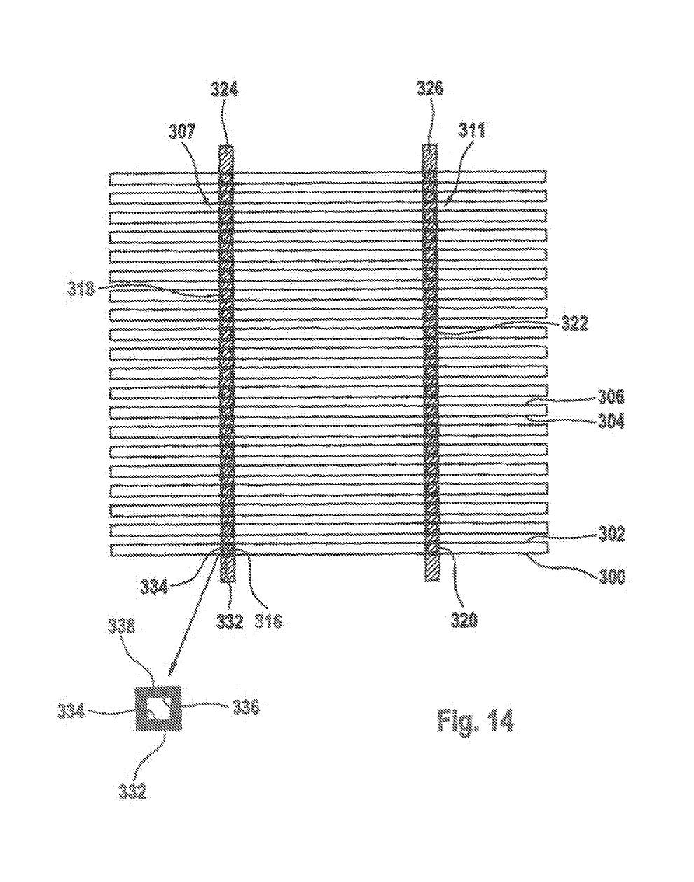

FIG. 14 shows another embodiment of a front-side contact;

FIG. 15 shows a third embodiment of a front-side contact;

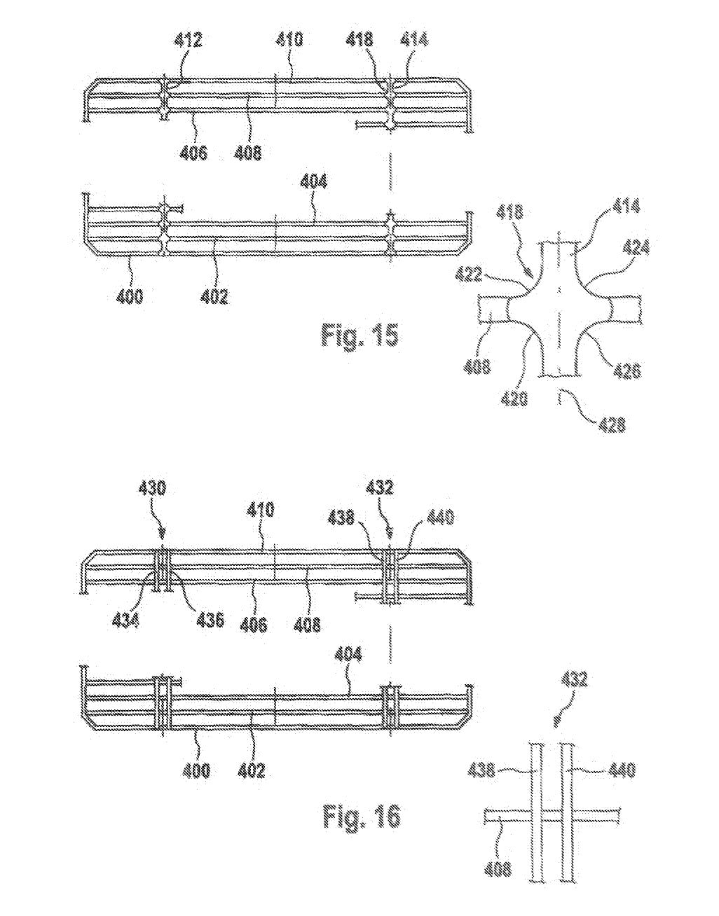

FIG. 16 shows a fourth embodiment of a front-side contact; and

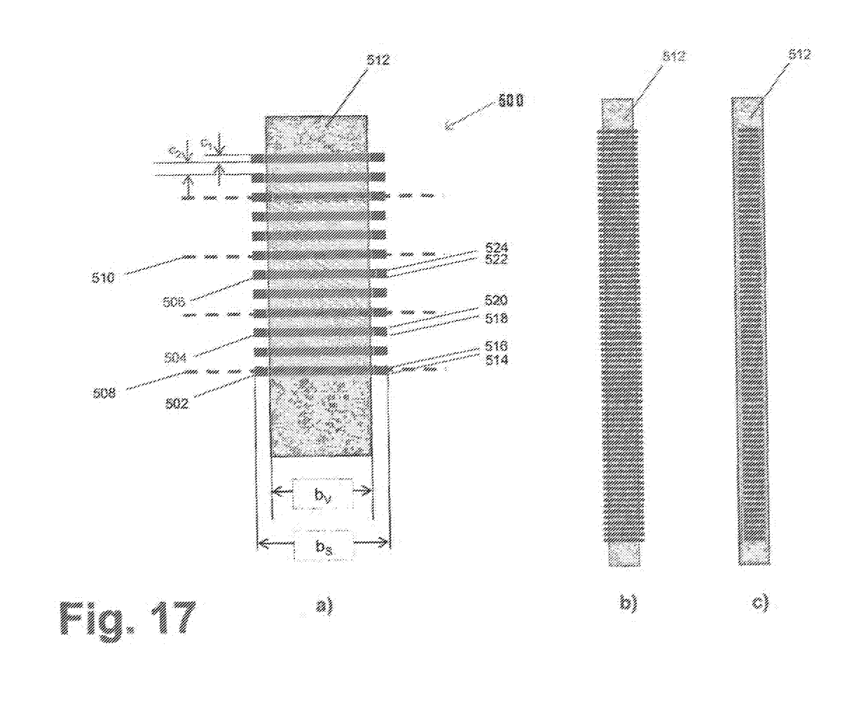

FIGS. 17a-17c show another embodiment of a front-side contact.

Excerpts of the back side of crystalline silicon solar cells that are composed of a p-silicon substrate with pn-junction and whose contacts on the front side are designed in the form of a front grid with busbars and finger-type current collectors can be taken from FIGS. 3 to 12. The respective back-side contact is formed by sintering an aluminum layer having recesses and soldering points or pads that are introduced into the recesses and that may be composed of silver or contain silver.

Although the back-side layer is designated as the aluminum layer, another material can also be used, such as one from the group of In, Ga, B or mixtures thereof. If this occurs, aluminum is to be understood as a synonym. Silver can also be exchanged for another suitable solderable material without departing from the invention.

In order to exclude the formation of cracks in the silicon material due to connectors cohesively connected to the pads, corresponding to the explanations for the figures, pads of special geometry are introduced into the recesses, whereby the soldering region, in which the connector is connected to the pads, runs at a distance to the alloy forming during tempering and thus production of the back-side contact composed of the aluminum layer and the silver pads, or connectors are connected to the pads in regions in which the pads are not contacted by the aluminum layer. Here, in the following explanations, basically the same elements will be provided with the same reference numbers.

FIG. 3 shows an excerpt of a back side of a solar cell in basic illustration, which has a back-side layer 30 composed of aluminum and having recesses in which soldering points or pads 32, in particular composed of silver, are disposed in a row, in order to cohesively connect the pads 32 to a connector 36.

An intermetallic compound (region 34) is formed in the transition region between the pads 32 and the layer 30. In order to avoid a formation of cracks, which might arise due to a cohesive connection between the connector 36 and the region 34 having the alloy, it is provided according to the invention that the connector 36 is exclusively and cohesively connected to the pad 32 outside of the region 34 of the intermetallic compound. This region is characterized in FIG. 3 by cross-hatching and by the reference number 35.

The region in which an intermetallic compound is no longer present, i.e., the region with which the connector 36 is cohesively connected, can be detected based on voltage measurements or micrographs, as has been previously explained. It can thus be recognized where the region of the intermetallic compounds terminates. In this connection, it can be basically established that in the region in which aluminum is no longer found, intermetallic compounds are basically no longer present, so that beginning from this region, the cohesive connection between the connector 36 and the pad 32 can be provided, in order to avoid the undesired crack formation.

Shown in FIG. 4 is an excerpt of a back side of a solar cell, in which several recesses 102 are also formed in a back-side layer such as an aluminum layer 100, and one of these recesses is shown. Several corresponding recesses 102 are thus likewise disposed along a straight line, along which a connector 104 extends, which is cohesively connected to the soldering points 106 running along the straight line. The soldering points are designated as pads below. The connector 104 can be a tin-coated copper strip.

As FIG. 4 illustrates, the pad 106 runs in the longitudinal direction of the connector 104 with its soldering edges 108, 110, at a distance to the facing layer edge 112, 114 of the recess 102. The soldering edges 108, 110 are adjacent to the so-called first edge region of the pad 106, over which the connector 104 extends. In other words, a gap 116, 118 runs between the edges 108, 112 and 110, 114, this gap basically extending to the silicon substrate.

In addition, the connector 104 and thus the soldering region 122 of the pad 106 covered by this connector run at a distance from the respective longitudinal or second edge region 124, 126, in which the pad 106 is contacted by the aluminum layer 100 or overlaps this layer, if need be, on the edge side. The corresponding longitudinal edge region 124, 126, which is shown raised from the center region in the figure, is composed of an intermetallic compound, i.e., an alloy of aluminum and silicon. The soldering region 122 of the pad 106 and the connector 104 runs at a distance to this region 124, 126. The distance between the facing longitudinal edge 128, 130 of the connector 104 and the facing end of the edge region 124, 126, i.e., the aluminum-silicon alloy is characterized by a in the figure, and lies between 0.5 mm and 5 mm.

The width of the respective gap 116, 118 is characterized by b and should lie between 0.5 mm and 10 mm, denoting the distance between the respective longitudinal edge 128, 130 of the connector 104 and the edge region 124, 126 of the pad 106. According to the example of embodiment of FIG. 4, the soldering edge 108, 110 of the pad 106 runs parallel to the layer edge 112, 114 of the recess 118. In fact, the mechanical load of the Ag/Al alloy region is excluded thereby, but high stresses can be built up in the pad 106 in the case of tensile forces acting on the connector 104, these stresses possibly leading to the circumstance that cracks are formed in the substrate. In order to transfer tensile forces that may occur to a longer line, whereby the stresses are reduced, the pad 106 has at least one recess 107, over which the connector 104 extends, so that this connector covers a total of four soldering edges, whereby the tensile forces are transferred to a longer line. The corresponding soldering edges are characterized by the reference numbers 108, 110, 111, 113.

FIG. 5 shows a pad 132 that is composed of a rectangular center region 134, which is contacted by the aluminum layer 100 or runs overlapping with this layer, and of end-side circular-shaped sections 136, 138. Consequently, soldering edges 140, 142, which are adjacent to the sections 136, 138, over which edges the connector 104 extends, and proceeding from these, the connector 104 is cohesively connected to the soldering region 122 of the pad 132, are geometrically formed so that a convexly running arcuate shape results. The total length of the soldering edges 140, 142 is selected based on the geometry in such a way that the length of the soldering edges 140, 142 covered by the connector 104 corresponds to at least 2.5 times, preferably at least three times the width B of the connector 104, even if this is not absolutely recognizable from the drawing.

Independently from this, the connector 104 likewise runs at a distance to the first or longitudinal edge regions 124, 126, in which the alloy between aluminum and silicon is formed.

In particular, based on the embodiment example of FIG. 5, it can also be recognized that the invention still applies when the connector 104 only covers two soldering edges 140, 142 of the pad 132, insofar as the connector 104 is cohesively connected to the pad 132 outside of the intermetallic compounds, thus outside of the longitudinal edge regions 124, 126.

According to the example of embodiment of FIG. 6, a pad 144 has the shape of a “dog bone” in top view, whereby the soldering edges over which the connector 104 extends have a concavely running arcuate shape. The corresponding soldering edges are characterized by the reference numbers 146, 148. The side sections of the pad 144 adjacent to the soldering edges 146, 148 run in a convex arcuate shape and merge into the two edge regions 124, 126 running in a straight line. The length of the section of the soldering edges 146, 148 relative to the width B of the connector 104 is designed also in such a way that it corresponds to at least 2.5 times, preferably at least three times the width B of the connector 104.

According to the example of embodiment of FIG. 7, a pad 154 is composed of two sections 156, 158, merging into one another in lenticular form or oval in top view, the edge regions of these sections running in a straight line, extending along the longitudinal axis of the connector 104. The alloys are formed in these regions, so that the corresponding edge regions are characterized by the reference numbers 124, 126.

By overlapping the sections 156, 158, front-side soldering edges 160, 162 covered by the connector 104 result, which have a V shape with convexly running legs in top view.

The example of embodiment of FIG. 8 introduces the geometry of a pad 164, which has a rectangular shape and substantially fills the recess 102 with the exception of the second edge regions that are covered by the connector 104. In these regions, the pad 164, i.e., its first edge regions, thus soldering edges 166, 168, have a concavely arcuate-shaped course with a total length relative to the region covered by the connector 104 that corresponds to at least 2.5 times, preferably at least three times the width B.

For increasing the distance of the pad 164 from the back-side layer 100 in the region of the connector 104, the edge regions of this layer facing the soldering edges 166, 168 of the pad 164 are also formed such that a concavely arcuate-shaped layer edge 170, 172 results each time. Consequently, the connector 104 covers a gap that has an elliptical geometry in top view.

In order to further reduce a tensile force that may act on a pad 174 via the connector 104, the example of embodiment of FIG. 9 provides that the pad 174 has recesses 176, 178, which, by way of example, have a circular geometry or an elliptical geometry in top view. The soldering edges, which are adjacent to the recesses 176, 178, are shown by the broken lines in the drawing. The longitudinal axis of the recess 178 having the elliptical geometry thus runs crosswise to the longitudinal axis of the connector 104. From the illustration in the drawing, it can be recognized additionally that the pad 174, corresponding to the example of embodiment of FIG. 5, is composed of a rectangular central section 134 and circular-shaped end sections 136, 138, whereby the soldering edges 140, 142 of the end sections 136, 138 run at a distance to the facing layer edges of the recess 102, as the drawing shows.

The second edge regions 124, 126 or longitudinal edge regions of the pad 174 run at a distance to the longitudinal edges 128, 130 of the connector 104.

In addition, the drawing shows that the circular recess 176 is completely covered by the connector 104 and the elliptical recess 178 is covered in the center region by the connector 104.

Additional embodiments of pads 180, 182 can be taken from FIGS. 10 and 11. In this case, the pad 180 according to FIG. 10 is composed of strip-shaped sections 184, 186, 188, 190 distanced from one another, so that the connector 104 consequently covers a total of eight soldering edges 194, 196, 198, 200, 202, 204, 206, 208. In this case, tensile forces that occur are distributed in such a way that crack formations are avoided and there is no detaching of the pad 180 or its strips 184, 186, 188, 190. For the example of embodiment of FIG. 11, the pad 182 has three rectangular recesses 210, 212, 214, so that the connector 104 likewise covers eight soldering edges, which are not characterized in more detail.

Independently from this, the pads 180, 182 with their outermost soldering edges 194, 208 in each case run at a distance to the layer edges 216, 218, which are covered by the connector 104.

The advantage of a good electrical contact to the aluminum layer 100 results due to the geometry relating thereto.

Due to a corresponding formation of the pads 180, 182—as in the previously explained pads according to the invention—the advantage results that the quantity of pad material to be used is reduced in comparison to known arrangements. This is then particularly advantageous if silver is used as the pad material.

FIG. 12 shows additional preferred embodiments of pads 250, 252, which are composed of strips running at a distance to one another, which form the geometry of an oval around their periphery. Several of the strips are characterized by way of example with the reference numbers 254, 256, 258 or 260, 262. The strips run crosswise or perpendicular to the connector 104. The intermetallic region is characterized by blackening. This region is formed by the contact between the pad strips and the aluminum. The crosspiece-shaped sections or strips 256, 258, 260, 262 not running in the intermetallic region each have two soldering edges, so that in accordance with the teaching of the invention, the force is distributed when tensile forces act on the connector 104. Further, the connector 104 in the illustration on the left in FIG. 12 runs over soldering edge 266 of the strip-shaped section 254 running on the inside of the pad, this section directly merging into the edge region of the pad 250, 252 having the intermetallic compound. In the example of embodiment of the illustration on the right in FIG. 12, in contrast, all of the strip-shaped section 260, 262 of the pad 252 running perpendicular to the longitudinal axis of the connector 104 run in regions in which they are covered by the connector 104 at a distance to the ellipse 264 symbolizing the intermetallic compound.

Preferred dimensions of the pad or soldering point are the following:
Length of the pad: 5 mm to 10 mm
Width of the pad: 5 mm
Length of the corresponding second edge region: 5 mm to 8 mm
Minimum width of the gap between pad and aluminum layer in the region
covered by the connector: 0.5 mm
Thickness of the pad: 10 μm to 15 μm
Surface area of the pad: as small as possible in order to save Ag
Width of the alloyed region: 0.1 mm to approximately 2 mm.

Based on the FIGS. 13 to 16, the teaching according to the invention will be explained on the basis of front contacts of a solar cell. Here, the same reference numbers are basically used for the same elements.

In the known way, so-called contact fingers 300, 302, 304, 306, which run essentially parallel to one another, are disposed on the front side of a solar cell. The contact fingers 300, 302, 304, 306 can be connected under one another at their ends, in order to also then make possible a flow of current if one contact finger in one region should be interrupted. Busbars 307, 311, which are composed of sections arranged in rows next to one another according to the invention, in the known way run crosswise to the lengthwise extension of the contact fingers 300, 302, 304, 306, which are symbolized according to FIG. 13 by filled squares 308, 310 or 312, 314 or by open rectangles, such as squares 316, 318 or 320, 322 according to FIG. 14. In each case, a connector 324, 326, which is cohesively connected to the busbars 307, 311, extends over the corresponding busbars 307, 311 or their sections 308, 310, 312, 314, 316, 318, 320, 322. An interconnection of solar cells is subsequently produced via the connectors 324, 326.

As can be seen from FIGS. 13 and 14, each busbar is not formed to be continuous, but is composed of the sections 308, 310, 312, 314, 316, 318, 320, 322, which are connected in an electrically conducting manner via the connectors 324, 326. In this way, each section 308, 310, 312, 314, 316, 318, 320, 322 extends over at least two contact fingers 300, 302, 304, 306.

Therefore, according to the example of embodiment of FIG. 13, each connector 324, 326 covers two soldering edges per pair of contact fingers 300, 302 or 304, 306, with the consequence that tensile forces are distributed and there is no danger of a crack formation. The soldering edges of the respective section 308, 310, 312, 314 are characterized, for example, with the reference numbers 328, 330 on section 308.

In the formation of sections 316, 318, 320, 322 in the shape of a hollow rectangle, two additional soldering edges are available, so that a total of four soldering edges are covered by the respective connector 324, 326 per pair of contact fingers 300, 302 or 304, 306, so that there is an increase in the distribution of tensile forces. The corresponding soldering edges of one of the sections-section 316 in the example of embodiment—are characterized by the reference numbers 332, 334, 336, 338.

In the example of embodiment of FIGS. 13 and 14, the respective section 308, 310, 312, 314, 316, 318, 320, 322 has a rectangular geometry in top view, but another geometry is also possible, in particular a circular or oval geometry.

In addition, the sections of the busbar can also be covered by more than two contact fingers 300, 302, 304, 306, so that correspondingly, the number of soldering edges is reduced.

Although the busbar 307, 311 according to the example of embodiment of FIGS. 13 and 14 is divided into individual sections, the teaching of the invention can also be realized when the busbar is formed to be continuous, as long as additional soldering edges are made available. This will be illustrated on the basis of FIGS. 14 and 15.

According to FIG. 15, contact fingers 400, 402, 404, 406, 408, 410 are connected by busbars 412, 414, which are expanded in width, however, in the contact region with the fingers 400, 402, 404, 406, 408, 410, as illustrated by the detailed illustration in FIG. 15. In this figure, the point of intersection 418 between the contact finger 408 and the busbar 414 is shown. It can be seen that the busbar 414 is expanded in the overlapping region or point of intersection 418, so that a total of four soldering edges 420, 422, 424, 426 are produced at the point of intersection 418, these edges running diagonally to the longitudinal direction 428 of the busbar 414. In this way, the soldering edges 420, 422, 424, 426 of the busbar 414 forming the longitudinal edges continually merge into the longitudinal edges of the contact finger 408, these edges not being characterized in more detail.

In the example of embodiment of FIG. 16, busbars 430, 432, which are formed as double strips, run perpendicular to the contact fingers 400, 402, 404, 406, 408, 410, i.e., each busbar 430, 432 is composed of two strip-shaped or line-shaped sections 434, 436 or 438, 440 running parallel to one another. Busbars 430, 432 with four longitudinal soldering edges result from this, as shown by the detailed illustration in FIG. 16. In this case, the respective longitudinal edge forming a soldering edge of the sections 434, 436, 438 440 of the busbars 430, 432 continually merges into the respective longitudinal edges of the contact fingers 400, 402, 404, 406, 408, 410, as is illustrated on the basis of FIG. 15.

According to the example of embodiment of FIG. 16, the soldering edges run in the longitudinal direction of the connector, thus in the tension direction, while a course crosswise or perpendicular to the longitudinal direction is provided in the other examples of embodiment. Mixed forms are also possible, as FIG. 15 illustrates, i.e., soldering edges can run crosswise to the longitudinal direction, obliquely to the longitudinal direction, and in the longitudinal direction, at least in sections.

Another embodiment to be highlighted for the teaching according to the invention of the configuration of a front-side contact of a solar cell can be taken from FIGS. 17 a) to 17 c). Thus busbar 500 is composed of strip-shaped sections, several of which are characterized by the reference numbers 502, 504, 506. The sections, which can have a rectangular geometry, have a width c₁. The distance between adjacent edges of two sections following one another amounts to c₂. Other geometries, such as an arcuate-shaped course for each section, is likewise possible, whereby a lengthening of the respective soldering edges results.

As can be seen from the illustration in the drawing according to FIG. 17 a), each section is not connected to a contact finger or grid finger 508, 510. In the embodiment example, the section 502 is connected to the finger 508. The fingers 508, 510 are indicated by the dashed lines.

A connector 512, which is cohesively connected to the sections 502, 504, 506, extends crosswise to these sections. Thus, according to FIGS. 17a) to 17c), the contact structure is composed of many individual sections 502, 504, 506 of contact material running crosswise to the direction of the connector 512, whereby a plurality of soldering edges are formed in a constricted space, several of these edges being characterized by the reference numbers 514, 516, 518, 520, 522, 524.

The tensile force of the connector 512 is uniformly distributed onto the individual n sections 502, 504, 506, i.e., contact structures, so that the force Fₙ=F_{connector}/2n at each soldering edge 514, 516, 518, 520, 522, 524.

If the connector exercises a force of, e.g., 30 N on the outer soldering edges of a related busbar, then the force for this case is that, in accordance with the teaching according to the invention, e.g., the busbar is divided into n=10 sections or structures, divided by 20, so that only 1.5 N will act on each soldering edge. In this way, the mechanical stress of the wafer is reduced and the stress is distributed onto 2n soldering edges.

The contact fingers or grid fingers 508, 510, which are characterized by the dashed lines, as mentioned, open up into several of the sections denoted contact structures, in order to assure the electrical connection of the current collector.

As results from the illustration in the drawing, several sections or contact structures, such as the contact structures 504, 506, each of which has two soldering edges, run between or outside of the fingers 508, 510, so that the mechanical stress can be effectively reduced.

It results from the illustrations of FIGS. 17 b) and 17 c) that the width of the sections 502, 504, 506, i.e., the contact structures, is independent of the width of the connector 512, i.e., is either larger or smaller than the width of the connector 512. According to FIG. 17 b), the strip-shaped sections or structures extend laterally outside of the connector 512, whereas in the embodiment of FIG. 17 c), the sections are completely covered by the connector 512.

Preferred measurements for the contact structure according to FIG. 17 are:
c₁=200 μm to 500 μm
c₂=200 μm to 500 μm
bᵥ=width of the connector 512, e.g. 1.5 mm, 1.8 mm and 2.0 mm
bₛ=width of the contact structure or of the section 502, 504, 506, e.g.
   1.0 mm to 1.8 mm for bᵥ=1.5 mm
   1.2 mm to 2.2 mm for bᵥ=1.6 mm
   1.8 mm to 2.4 mm for bᵥ=2.0 mm.

1-18. (canceled)

19. A solar cell comprising:
a semiconductor substrate with a front side and a back side;
a back-side contact on the back side;
a front-side contact on the front side, the front-side contact having contact fingers running parallel to one another and at least one busbar running crosswise to the contact fingers; and
a connector running along and cohesively connected to the at least one busbar, wherein the least one busbar includes sections having soldering edges and the connector extends over the sections.

20. The solar cell according to claim 19, wherein the sections are formed in such a way that two contact fingers are each connected to the at least one busbar.

21. The solar cell according to claim 20, wherein the section connecting the two contact fingers has, in top view, an annular or hollow-rectangular geometry having four soldering edges.

22. The solar cell according to claim 19, wherein the at least one busbar has, in a longitudinal direction, at least four longitudinal soldering edges.

23. The solar cell according to claim 19, wherein the at least one busbar has an expanded width in a contact region with the contact fingers.

24. The solar cell according to claim 19, wherein the at least one busbar has strip-shaped sections that run perpendicular to and are cohesively connected to the connector.

25. The solar cell according to claim 24, wherein at least several of the strip-shaped sections are exclusively connected to a contact finger.

26. The solar cell according to claim 19, wherein the back-side contact has a layer with recesses of a first electrically conducting material and solderable soldering points in the recesses, the solder points of a second, different electrically conducting material that forms an intermetallic compound in the contact region with the first electrically conducting material, whereby soldering points disposed in at least two recesses can be connected to a connector running along a straight line in a soldering region of each point in each case and the connector extends at a distance to the layer over soldering edges of the soldering point, wherein the connector is cohesively connected to the soldering points exclusively outside of the intermetallic compound, and/or that the connector extends over at least three soldering edges, whereby the at least three soldering edges running crosswise to the straight line have a length covered by the connector that is at least 2.5 times the width B of the connector.

27. The solar cell according to claim 26, wherein a first soldering edge is a first edge region of the soldering point intersected by the straight line, this region running at a distance to the layer or its layer edge covered by the connector.

28. The solar cell according to claim 26, wherein the soldering point disposed in the recess has at least two sections at a distance from one another, at least in the region of the recess covered by the connector.

29. The solar cell according to at least claim 28, wherein each of the sections of the soldering point that are at a distance from one another have two soldering edges.

30. The solar cell according to claim 29, wherein the sections of the soldering point are disposed separately from one another in the recess.

31. The solar cell according to claim 27, wherein the soldering edges adjacent to the first edge region follow an arcuate section, at least in the soldering region relative to facing layer edges.

32. The solar cell according to claim 27, wherein the soldering point is composed of two sections merging into one another in a lenticular manner or oval-shaped in top view, the longitudinal axes of which run along the straight line, whereby the soldering edges of the first edge region have a V geometry with curved running legs.

33. The solar cell according to claim 27, wherein the soldering point has a rectangular geometry in top view, whereby the respective soldering edge of the first edge region has a concavely running arcuate geometry and facing layer edges each have a concavely running arcuate geometry.

34. The solar cell according to claim 26, wherein the soldering point, in its soldering region, has at least one circular or oval recess that is covered at least in regions by the connector when it is soldered on.

35. The solar cell according to at least claim 34, wherein the circular recess is completely covered by the connector and/or the oval recess running with its longitudinal axis crosswise to the longitudinal axis of the connector is preferably covered exclusively in regions.

36. The solar cell according to claim 27, comprising a minimum distance between soldering edges of the first edge region of the soldering point and facing layer edges of the layer is greater than or equal to 500 μm.

37. The solar cell according to claim 36, wherein the minimum distance is less than or equal to 10 mm.

38. The solar cell according to claim 26, comprising a minimum distance between the edge region of the cohesive connection between the connector and the soldering point and the intermetallic compound that greater than or equal to 500 μm and less than or equal to 2 mm.
